(19) United States
(12) Patent Application Publication
(10) Pub. No.: US 2012/0017970 A1
(43) Pub. Date: Jan. 26, 2012

(54) Method and System of Layered Thin-Film Device With Ceramic Substrates

(75) Inventors: Nathan W. Cheung, Kowloon (HK); Chung Chan, Kowloon (HK)

(73) Assignee: SILICON CHINA (HK) LIMITED, Kowloon (HK)

(21) Appl. No.: 12/854,190

(22) Filed: Aug. 11, 2010

(30) Foreign Application Priority Data
Jul. 20, 2010 (CN) 201010234211.3

(51) Int. Cl. H01L 27/142; H01L 31/18; H01L 31/0203

(52) U.S. Cl. 136/251; 136/244; 438/66; 257/E31.117; 257/E27.123

(57) ABSTRACT

A method for forming solar cells includes providing a crystalline silicon substrate which can be mono-, multi-, or poly-crystalline, the substrate being defined by a first thickness, the substrate including a first surface and a second surface, the first surface on an opposite side of the second surface. The method also includes forming a separation region within the first thickness, the separation region including hydrogen species, the separating region being substantially parallel to the first surface, the separation region defining a first portion and a second portion within the thickness. Additionally, the method includes providing a mould structure defining a support region on the first surface in which a layer of ceramic material is formed, followed by mould removal. Additionally, the method includes forming electrical devices on the first portion and packaging formed solar cells, including interconnections for solar tile applications.

### CROSS-REFERENCES TO RELATED APPLICATIONS

Not applicable

### BACKGROUND OF THE INVENTION

The present invention relates generally to solar energy techniques. In particular, the present invention provides a method and resulting device fabricated from a hydrogen separation process using a crystalline material suitable for photovoltaic applications. More particularly, the present invention provides a method and resulting device for manufacturing photovoltaic regions that is supported by ceramic substrates. Merely by way of example, the invention has been applied to solar panels, commonly termed modules, but it would be recognized that the invention has a much broader range of applicability.

Greenhouse gases are evolving rapid rates, leading to global warming. As the population of the world increases rapidly to over six billion people, there has been an equally large consumption of energy resources, which leads to additional greenhouse gases. Often times, conventional energy comes from fossil fuels, including oil and coal, hydroelectric plants, nuclear sources, and others. As merely an example, further increases in oil consumption have been projected. Developing nations such as China and India account for most of the increase, although the United States remains the biggest consumer of energy resources. In the U.S., almost every aspect of our daily lives depends, in part, on oil. These aspects include driving to and from work, heating our homes, and operating large machines for construction and the like.

Oil is becoming increasingly scarce. As time further progresses, an era of “cheap” and plentiful oil is coming to an end. Oil will eventually disappear, which could possibly take us back to primitive times. Accordingly, other and alternative sources of energy have been developed. Modern day society has also relied upon other very useful sources of energy. Such other sources of energy include hydroelectric, nuclear, and the like to provide our electricity needs. Such electricity needs range from lighting our buildings and homes to operating computer systems and other equipment and the like. Most of our conventional electricity requirements for these home and business use come from turbines run on coal or other forms of fossil fuel, nuclear power generation plants, and hydroelectric plants, as well as other forms of renewable energy. A popular form of renewable energy has been solar, which is derived from our sun.

Our sun is essential for solar energy. Solar energy possesses many desired characteristics. As noted above, solar energy is renewable. Solar energy is also abundant and clean. Conventional technologies developed often capture solar energy, concentrate it, store it, and convert it into other useful forms of energy. A popular example of one of these technologies includes solar panels. Such solar panels include solar cells that are often made using silicon bearing materials, such as polysilicon or single crystal silicon. An example of such solar cells can be manufactured by various companies that span our globe. Such companies include, among others, Q Cells in Germany, Sun Power Corporation in California, Suntech of China, and Sharp in Japan. Other companies include BP Solar and others.

Unfortunately, solar cells still have limitations although solar panels have been used successfully for certain applications. As an example, solar cells are often costly. Solar cells are often composed of silicon bearing wafer materials, which are difficult to manufacture efficiently on a large scale. Availability of solar cells made of silicon is also somewhat scarce with limited silicon manufacturing capacities. These and other limitations are described throughout the present specification, and may be described in more detail below.

From the above, it is seen that techniques for improving solar devices is highly desirable.

### BRIEF SUMMARY OF THE INVENTION

The present invention relates generally to solar energy techniques. In particular, the present invention provides a method and resulting device fabricated from a hydrogen separation process using a crystalline material suitable for photovoltaic applications. More particularly, the present invention provides a method and resulting device for manufacturing photovoltaic regions that is supported by ceramic substrates. Merely by way of example, the invention has been applied to solar panels, commonly termed modules, but it would be recognized that the invention has a much broader range of applicability.

According to an embodiment, the present invention provides a method for manufacturing a solar cell. The method includes providing a crystalline silicon substrate, the substrate being defined by a first thickness, the substrate including a first surface and a second surface, the first surface on an opposite side of the second surface. The method also includes forming a separation region within the first thickness, the separation region including hydrogen species, the separating region being substantially parallel to the first surface, the separation region defining a first portion and a second portion within the thickness, the first portion being within a second thickness from the first surface. Additionally, the method includes providing a mould structure on the first surface, the mould structure defining a support region. Furthermore, the method includes forming a layer of ceramic material within the support region. Also, the method includes removing the mould structure. Additionally, the method includes removing the second portion. Moreover, the method includes forming electrical devices on the first portion.

According to another embodiment, the present invention provides a photovoltaic device. The device includes a supporting layer, the supporting layer consisting essentially of ceramic material, the supporting layer being characterized by a first thickness, the ceramic material being characterized by a gas permeability level, the supporting layer including a first surface and a second surface. The device also includes a photovoltaic layer including a first side and a second side, the photovoltaic layer being characterized by a thickness of less than ten microns, the photovoltaic layer overlying the first surface of the supporting layer, the first side being coupled to the supporting layer, the photovoltaic layer consisting essentially of silicon material. Additionally, the device includes a plurality of electrical contacts coupled to the photovoltaic layer.

According to yet another embodiment, the present invention provides a photovoltaic device. The device includes a supporting layer, the supporting layer consisting essentially of ceramic material, the supporting layer being characterized by a first thickness, the ceramic material being characterized by a gas permeability level, the supporting layer including a first surface and a second surface, the first surface being reflective, the ceramic material being solidified from a fluidic ceramic material. The device also includes a bonding layer, the bonding layer including adhesive material. Furthermore, the device includes a photovoltaic layer including a first side and a second side, the photovoltaic layer including doped regions, the doped regions including a first type and a second type of impurities, layer being characterized by a thickness of less than ten microns, the photovoltaic layer overlying the first surface of the supporting layer, the first side being coupled to the supporting layer through the bonding layer, the photovoltaic layer consisting essentially of silicon material, the photovoltaic layer including doped regions. Also, the device includes a plurality of electrical contacts coupled to the photovoltaic layer.

According to further embodiment, the present invention provides a packaged solar cells' structure for solar tile application. The packaged solar cell includes a photovoltaic device, the photovoltaic device including first side and second side and consisting of supporting layer and photovoltaic layer. The supporting layer is consisting essentially of ceramic material, the supporting layer being characterized by a first thickness, the ceramic material being characterized by a gas permeability level, the supporting layer including a first surface and a second surface. The photovoltaic layer includes a first side and a second side, the photovoltaic layer being characterized by a thickness of less than ten microns, the photovoltaic layer overlying the first surface of the supporting layer, the first side being coupled to the supporting layer, the photovoltaic layer consisting essentially of silicon material. The packaged solar cell also includes protective layer covering the first side and second side of photovoltaic device. The packaged solar cell further includes positive and negative electrical connectors for electrical connection to other packaged solar cells in series. The present invention can also provide electrical connection to other packaged solar cells in parallel.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a hydrogen co-implant to form a thin layer of photovoltaic material. Since the layers are very thin, multiple layers of photovoltaic regions can be formed from a single conventional silicon or other like material wafer. In a preferred embodiment, the present thin layer exfoliated by hydrogen implant and thermal treatment can be provided on a ceramic substrate, which will serve as a support member. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIGS. 1-8 are simplified diagrams illustrating a process for fabricating a photovoltaic structure according to an embodiment of the present invention.

FIG. 9 is a simplified diagram illustrating a photovoltaic structure according to an embodiment of the present invention.

FIG. 10 is a simplified diagram illustrating a photovoltaic structure according to an embodiment of the present invention.

FIGS. 11 and 12 are simplified diagrams illustrating a photovoltaic structure including silicon nitride layer according to an embodiment of the present invention.

FIG. 13 is a simplified diagram illustrating a photovoltaic structure including two layers of ceramic according to an embodiment of the present invention.

FIG. 14 is a simplified diagram illustrating a photovoltaic structure including a bonding layer according to an embodiment of the present invention.

FIG. 15 is a simplified diagram illustrating a photovoltaic structure including a mirror according to an embodiment of the present invention.

FIGS. 16 and 17 are diagrams illustrating a packaged solar cell with electrical connectors according to an embodiment of the present invention.

FIG. 18 is a diagram illustrating the electrical connection of packaged solar cells according to an embodiment of the present invention.

### DETAILED DESCRIPTION OF THE INVENTION

The present invention relates generally to solar energy techniques. In particular, the present invention provides a method and resulting device fabricated from a hydrogen separation process using a crystalline material suitable for photovoltaic applications. More particularly, the present invention provides a method and resulting device for manufacturing photovoltaic regions that is supported by ceramic substrates and provides a packaged solar cell structure for solar tile application. Merely by way of example, the invention has been applied to solar panels, commonly termed modules, but it would be recognized that the invention has a much broader range of applicability.

As explained above, the lack of silicon material has been a challenge in manufacturing solar panels on large scale. Over the past, various conventional techniques have been developed to produce cost-efficient solar panels. Unfortunately, conventional techniques are often inadequate in various ways. More specifically, conventional techniques often involve reducing the amount of silicon material used for manufacturing solar panels. However, solar panels that are manufactured with reduced amounts of silicon materials often fail to meet performance goals (e.g., being able to produce a desired amount of energy per unit area).

Typically, the solar cell layers in conventional solar panels have a thickness of two hundred to three hundred microns. The thickness of conventional solar layers is related to a variety of performance metrics, such as rigidity of the solar cells, amount of energy that can be generated, etc. With conventional solar cell structure, two hundred to three hundred microns of thickness is necessary for solar panels to meet these performance metrics. At the same time, manufacturing solar cell at this thickness level means much silicon material is needed for manufacturing solar cells. In contrast, solar cells structures according to embodiments of the present invention are manufactured using much less silicon material.

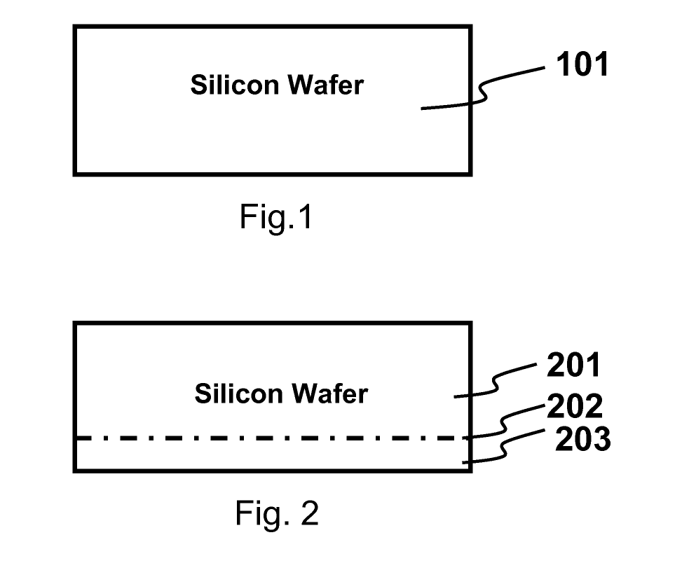

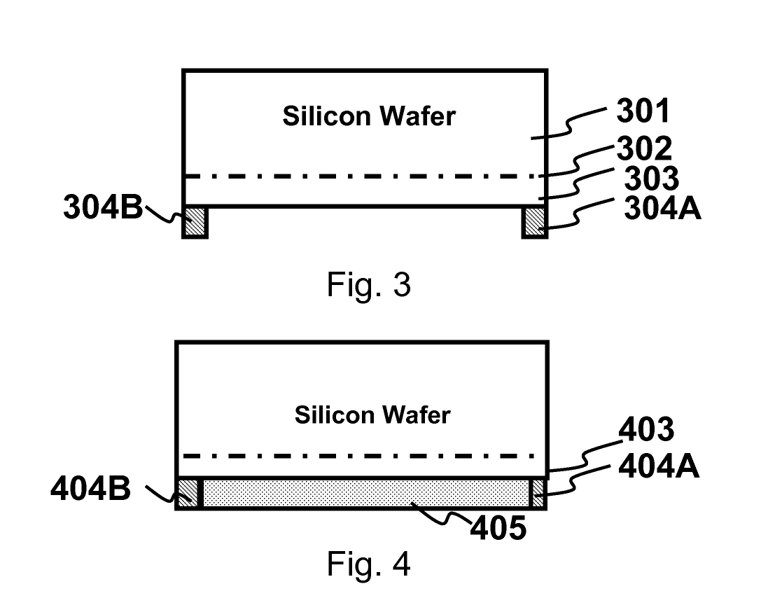

FIGS. 1-8 are simplified diagrams illustrating a process for fabricating a photovoltaic structure according to an embodiment of the present invention. This diagram is merely an example, which should not unduly limit the scope of the claims. One of ordinary skill in the art would recognize many variations, alternatives, and modifications.

As shown in FIG. 1, a piece of crystalline silicon wafer 101 is provided. In a specific embodiment, the wafer consists mainly of monocrystalline silicon materials. Typically, monocrystalline silicon material affords better efficiency in comparison to many other types of photovoltaic materials. But it is understood that other types of photovoltaic material (e.g., polysilicon material or microcrystalline material) may be used as well. In a specific embodiment, the silicon wafer 101 is about 200 to 300 microns in thickness.

As shown in FIG. 2, a separation layer 202 is created. The separation layer 202 divides the silicon wafer into two portions: portion 201 and portion 203. In a specific embodiment, hydrogen species are introduced specifically for the purpose for removing a layer of silicon material (i.e., the portion 203). According to the embodiments, the thickness of the portion 203 is predetermined in accordance with the amount of photovoltaic material needed for a solar device and the process used. In a specific embodiment, a hydrogen implantation process is utilized to introduce hydrogen species into the separation layer 202 through the portion 203. The thickness of the portion 203 is thus directly related to the degree of penetration of hydrogen species. For example, the thickness of the portion 203 is determined by the energy and concentration associated with the hydrogen implantation process. For example, a thickness of approximately two microns is a desirable thickness for a layer of photovoltaic material that can be used in a solar cell structure. Depending upon application, hydrogen species may be implemented according to various parameters or by multiple implantation steps. In a specific embodiment, the hydrogen implantation is performed at 200 keV with a dose range of 2E16/cm² to 2E18/cm². In another specific embodiment, lower energy phosphorus or boron particles are implanted into the surface of portion 203 to form emitter or a back surface field layer, followed by deposition of a metal layer to form the mirror material as well as an ohmic contact. In yet another specific embodiment, a layer of diffusion barrier (e.g. silicon nitride) is deposited on the hydrogen implanted wafer surface.

One or more mould structures 304A and 304B are coupled to the portion 303 of the silicon material. Depending on the application, the mould structures can be made in various ways. In a specific embodiment, mould structures are made using spacer materials that are compatible with foundry processes. For example, polysilicon material and other types of compounds may be used for the spacer material. It is to be appreciated that the mould structures afford flexibility during the manufacturing process, as many arbitrary shapes and thickness may be used for the mould structures to suit for specific applications.

As shown in FIG. 4, ceramic material 405 is filled within a space defined by the mould structures 404A and 404B. For example, fluidic ceramic material is provided to fill into the space. The expression “fluidic ceramic material,” as used herein, relates to ceramic materials that are particulates in a binder/liquid, such as a ceramic slurry. Fluidic ceramics are moldable materials which, when solidified, form a ceramic as, for example, through firing of the material. According to embodiment, the ceramic material can be highly reflective, or a reflective mirror can be integrated in between ceramic and silicon layer. Depending on the application, various types of ceramic materials may be used. For example, silicon dioxide powder, alumina powder or silicon carbide powder can be used. Optimum volume of liquid binder such as aluminum phosphate, potassium silicate, or colloidal silicate is required to mix with powder to form the fluidic ceramic material. In a specific embodiment, an additional layer of adhesive material is coated on the surface of silicon material 403 and used to promote adhesion of ceramic material 405 to the portion 403 of silicon material. The adhesive material should be prepared before coupling of spacer. In certain embodiments, the ceramic material 405 as shown are planarized to properly fit into the space between the spacer structures. Various shapes of ceramic material can be formed depending upon the mould structure and the desired final use of the photovoltaic material. As shown in the FIGS., a tile shape is an exemplary form; however, any arbitrary three-dimensional structure may be formed according to the processes of the present invention.

It is to be appreciated that the ceramic material used provide various advantages. Among other things, the use of fluidic ceramic material enables the addition of strengthening films attaching to the transferable crystalline layer to realize high-yield layer transfers. It also enables the mirror integration for increasing of solar cell efficiency. In various embodiments, fluidic ceramic material is used, and it conforms to the surface of the portion 403 of the silicon material, which is often rough and/or porous, thereby enabling multiple layer transfers from a single silicon wafer or ingot. The use of fluidic ceramic material alleviates adhesion problems associated with warping of wafers and dust particle trapping. Essentially, the use of fluidic ceramic material enables the addition of strengthening layers and optical mirror that are attached to the transferable crystalline layer. In certain applications, the use of flowing fluidic ceramic material enhances the adhesion to the transferred layer.

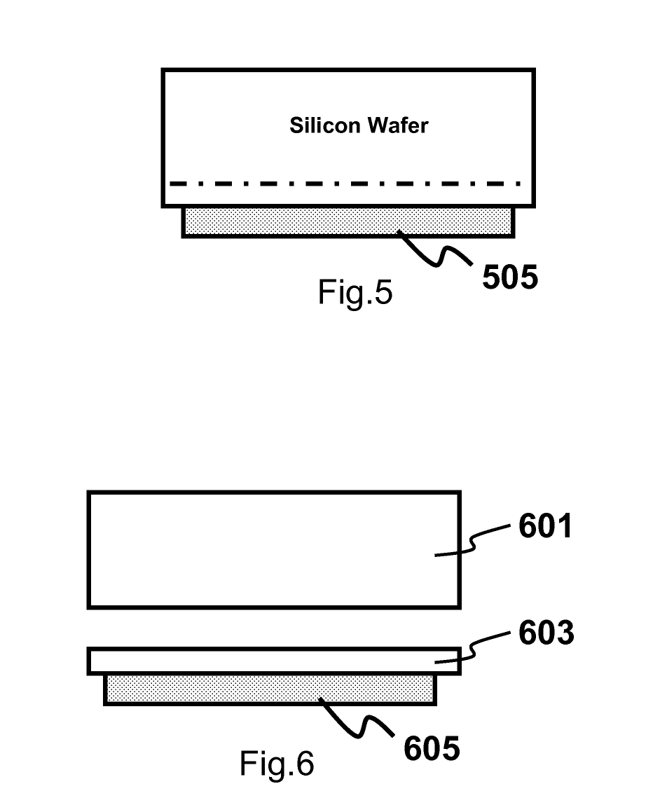

After ceramic material is filled into the spaces defined by the mould structures, mould structures are removed, which results in a structure as shown in FIG. 5. As described above, the mould structure may consist of foundry compatible spacer material. Such material, consequently, may be removed using foundry compatible process, such as physical removal, chemical removal, polishing, and other processes. In addition to removing the mould structures, additional processes may be performed on the ceramic structures. For example, the ceramic material 505 is cured before removing mould structure. The curing process involves baking of the whole structure in oven or hotplate. Curing temperature ranges from 50 to 400 degrees Celsius. The curing step makes the ceramic mechanically rigid enough for the subsequent processing.

Next, the bulk of the silicon material is removed. As shown in FIG. 6, the portion 601 of the silicon material is detached from the silicon layer 603. With the portion 601 removed, a structure including the portion 603, and the ceramic material 605 remains. According to certain embodiments, a thermal treatment process is performed on the structure to cause separation at the separation layer underlying the surface region of the crystalline silicon substrate and to exfoliate the portion 603 of silicon material, while the thickness of silicon material remains attached to the ceramic material 605. As an example, a roughened region is formed defining the portion 603 of the silicon material. In a specific embodiment, the thermal treatment process (e.g., exfoliation process, etc.) is performed at approximate a range of three hundred to six hundred degrees Celsius. As an example, the removed portion of the substrate is used for manufacturing other solar cell structures. Depending on the application, other foundry compatible processes may be used to remove the portion 601 from other structures.

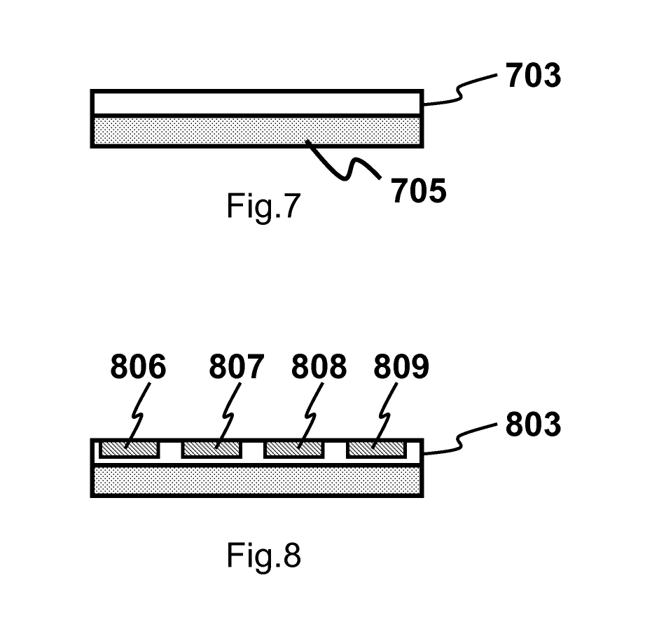

As shown in FIG. 7, various processes are performed to prepare the ceramic material 705. In a specific embodiment, physical polishing process is performed on the ceramic substrate to smooth out the ceramic surface for better performance. In another specific embodiment, the surface and edge area of the ceramic substrate will be treated by plasma exposure, thin-film coating, or deposition processes to prevent liquid penetration during subsequent device processing steps.

After the structure 700 is processed, further steps are taken to form electrical devices. As shown in FIG. 8, various electrical devices are formed on the portion 803 of the silicon material. According to a specific embodiment, regions 806 and 808 are doped with a first type of dopant (e.g., n type), and regions 807 and 809 are doped with a second type of dopant (e.g., p type), thereby forming basis of one or more p-n junctions. Depending on the application, spacing, size, and arrangement of the doped regions can be determined and/or modified. For example, for solar cell related applications, spacing, size, and arrangement of the doped regions are set for optimal collection of photogenerated carriers and the best electrical characteristics. In addition, not shown in FIG. 8, other electrical structures may be created. For example, electrical contacts may be formed onto the doped regions. The other exposed regions may be covered by anti-reflection and passivation layer such as silicon nitride or silicon dioxide.

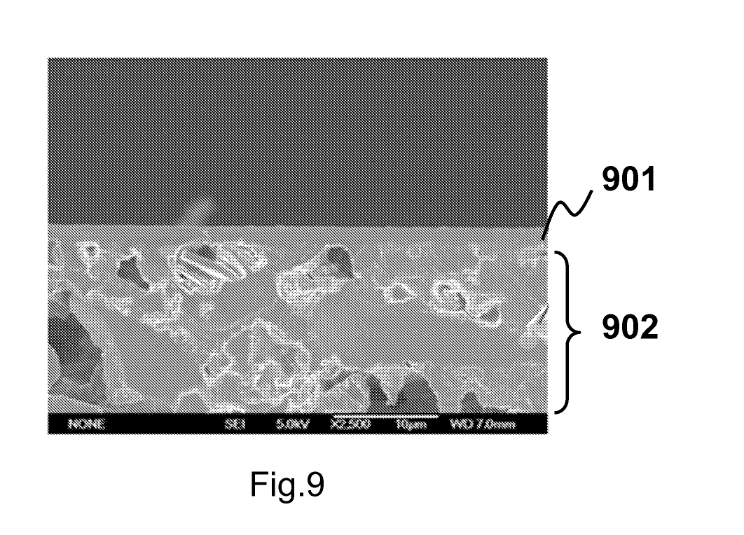

FIG. 9 is a simplified diagram illustrating a photovoltaic structure according to an embodiment of the present invention. This diagram is merely an example, which should not unduly limit the scope of the claims. One of ordinary skill in the art would recognize many variations, alternatives, and modifications. As shown in FIG. 9, a thin layer 901 of silicon material is bonded to the ceramic material 902. As shown in FIG. 9, the thickness of the thin layer 901 is only a few microns. Also shown in FIG. 8, the ceramic material 902 includes some pores. As an example, slightly gas permeable ceramic material is used to facilitate self-degassing in various elevated temperature/curing steps. According to an embodiment, the surface of the ceramic material 902 that bonds to the layer 901 is smooth and reflective, which helps light absorption for photovoltaic applications.

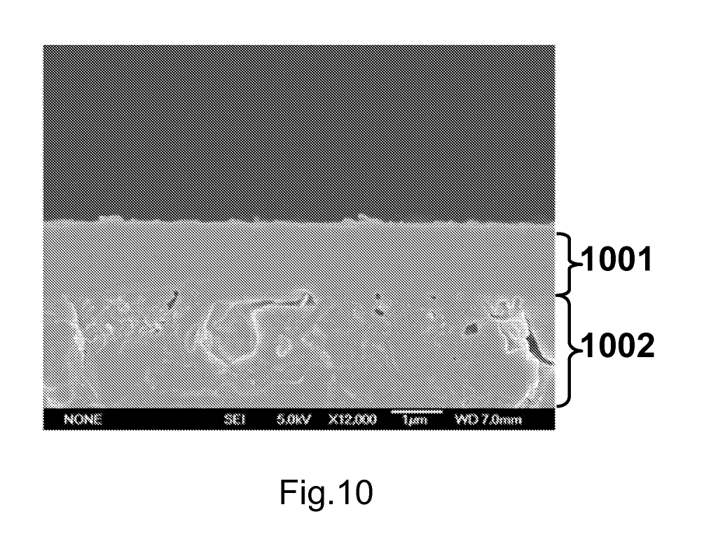

FIG. 10 is a simplified diagram illustrating a photovoltaic structure according to an embodiment of the present invention. This diagram is merely an example, which should not unduly limit the scope of the claims. One of ordinary skill in the art would recognize many variations, alternatives, and modifications. As shown in FIG. 10, a thin layer 1001 of silicon material is bonded to the ceramic material 1002. As shown in FIG. 10, the thickness of the thin layer 1001 is only a few microns.

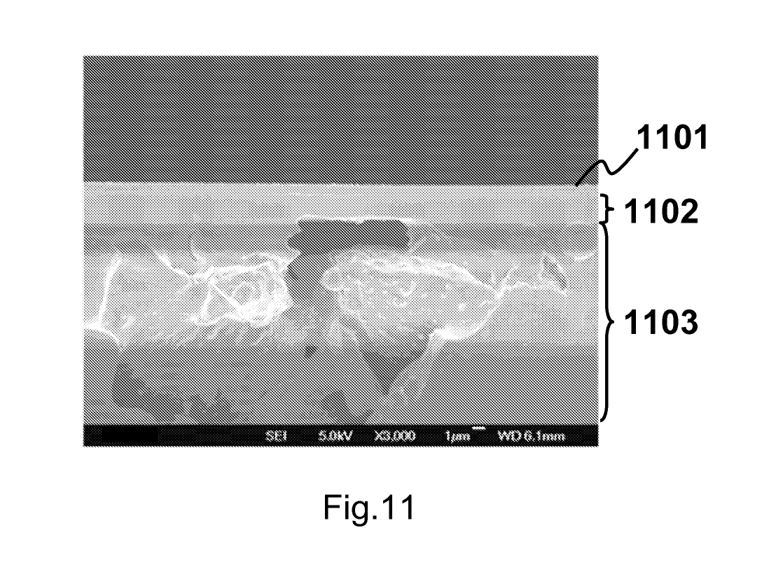

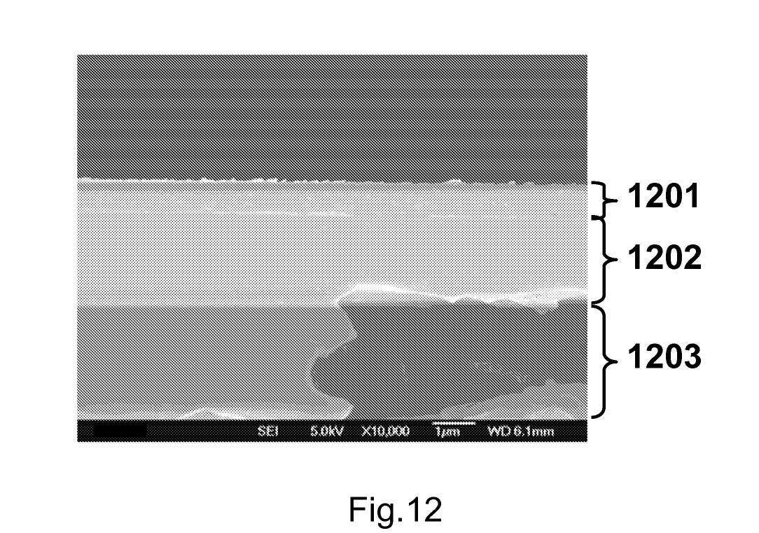

FIGS. 11 and 12 are simplified diagrams illustrating a photovoltaic structure including silicon nitride layer according to an embodiment of the present invention. This diagram is merely an example, which should not unduly limit the scope of the claims. One of ordinary skill in the art would recognize many variations, alternatives, and modifications. As shown in both FIGS. 11 and 12, a layer 1101 of silicon material is coupled to a layer 1102 of silicon nitride material. The silicon nitride material, among other things, strengthens the layer 1101 and acts as diffusion barrier. The layer 1102 is coupled to the ceramic material 1103. As shown, both the layer 1101 and the layer 1102 are few microns in thickness. As an example, slightly gas permeable ceramic material is used to facilitate self-degassing in various elevated temperature/curing steps. According to an embodiment, the ceramic substrate is cured to serve as a substrate for the silicon layers.

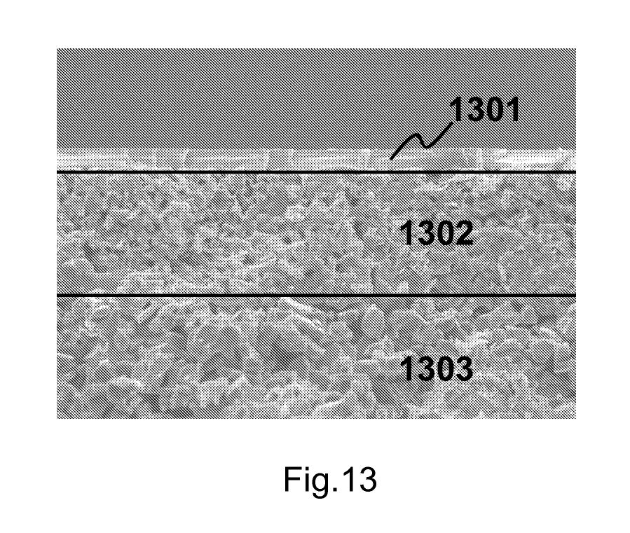

FIG. 13 is a simplified diagram illustrating a photovoltaic structure including two layers of ceramic according to an embodiment of the present invention. This diagram is merely an example, which should not unduly limit the scope of the claims. One of ordinary skill in the art would recognize many variations, alternatives, and modifications. As shown in FIG. 13, a silicon layer 1301 is coupled to the ceramic material 1302. Ceramic material 1302 is coupled to the other ceramic material 1303. The first ceramic material 1302 is used as adhesive to increase adhesion of silicon layer 1301 on ceramic material 1303.

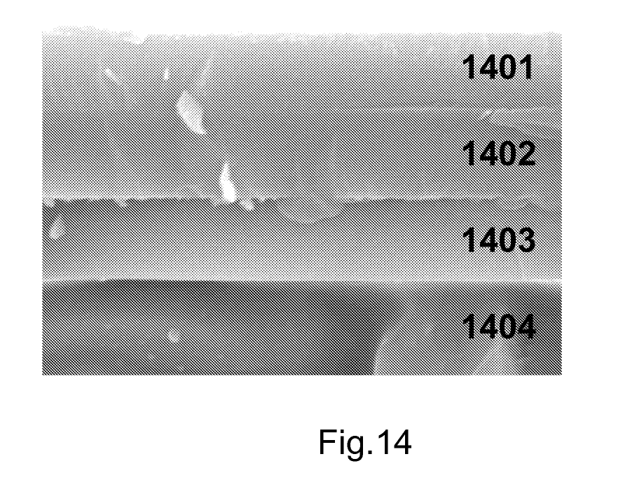

FIG. 14 is a simplified diagram illustrating a photovoltaic structure including a bonding layer according to an embodiment of the present invention. This diagram is merely an example, which should not unduly limit the scope of the claims. One of ordinary skill in the art would recognize many variations, alternatives, and modifications. As shown in FIG. 14, a layer of silicon 1401 is coupled to a layer of silicon nitride 1402 for silicon strengthening and diffusion barrier. Adhesive material 1403 which is a continuous bonding layer added between silicon nitride 1402 and ceramic material 1404 to act as a strong adhesive.

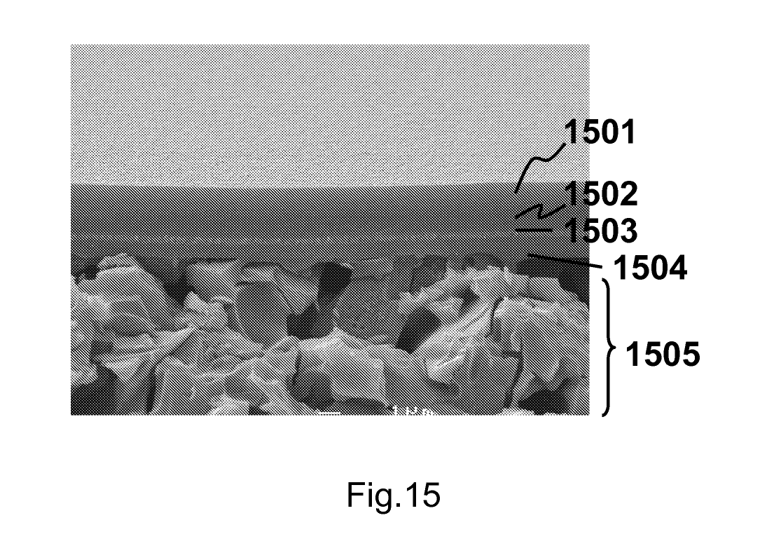

FIG. 15 is a simplified diagram illustrating a photovoltaic structure including a mirror according to an embodiment of the present invention. This diagram is merely an example, which should not unduly limit the scope of the claims. One of ordinary skill in the art would recognize many variations, alternatives, and modifications. As shown in FIG. 15, a mirror layer 1503 was inserted in between two layer of silicon nitride 1502 and 1504. A silicon layer 1501 is coupled to the first silicon nitride layer 1502 and a second silicon nitride layer is coupled to the ceramic material 1505.

Solar cells structures according to embodiments of the present invention can be used for conventional solar panels. Moreover, the special design of photovoltaic layer and ceramic substrate makes solar tile possible. Conventional silicon solar cells are required to be connected by silver line using solder and it is protected by EVA, glass and TPT in module form. In contrast, solar cells structures according to embodiments of the present invention are manufactured in a way that can be easily connected and totally replace conventional tiles.

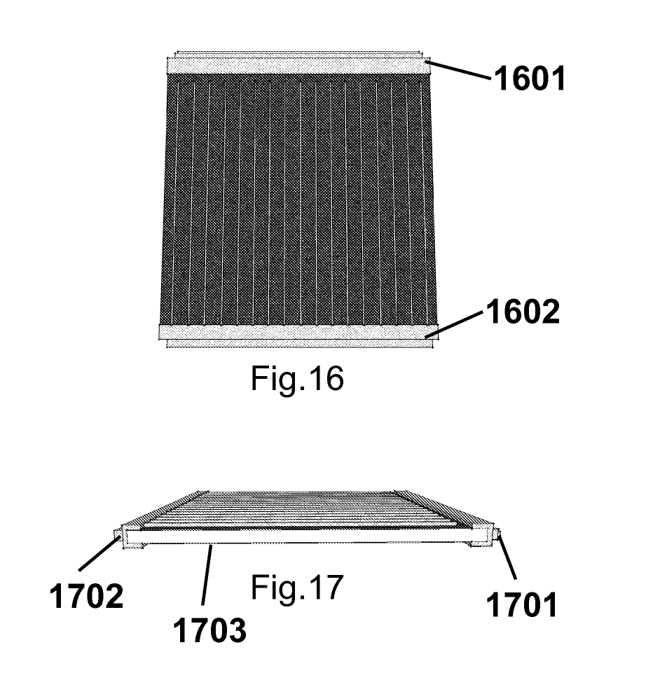

FIGS. 16 and 17 are diagrams illustrating a packaged solar cell with electrical connectors according to an embodiment of the present invention. This diagram is merely an example, which should not unduly limit the scope of the claims. One of ordinary skill in the art would recognize many variations, alternatives, and modifications. As shown in FIGS. 16 and 17, electrical connectors 1601, 1602, 1701, and 1702 were attached to the edges of the solar cell. Positive connectors 1601, 1701 and negative connectors 1602, 1702 are opposite to each other. Positive connectors are connected to p-type electrode of the solar cell and negative connectors are connected to n-type electrode of the solar cell. This can be done by conductive glue or soldering. The connectors are male 1601, 1701 and female 1602, 1702 structure for connecting the solar cell in series. The female connector is generally a receptacle that connects to and holds the male connector in such a way that the packaged solar cells can be electrical connected. The body of the photovoltaic device 1703 is protected by covering of protective layers on first surface and second surface of photovoltaic device.

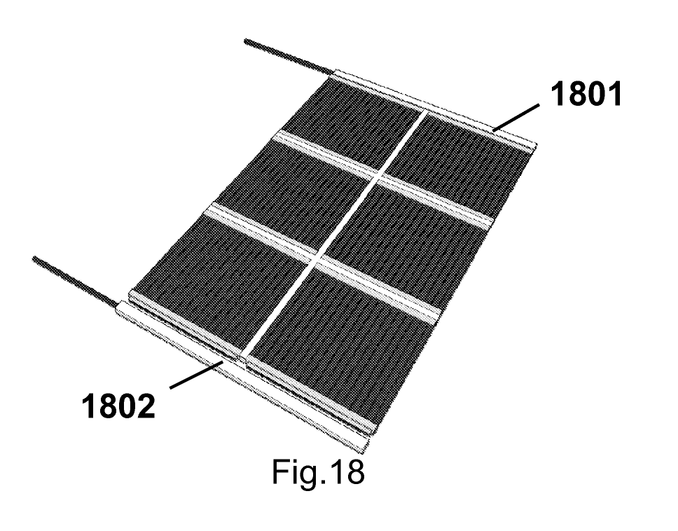

FIG. 18 is a diagram illustrating the electrical connection of packaged solar cells according to an embodiment of the present invention. This diagram is merely an example, which should not unduly limit the scope of the claims. One of ordinary skill in the art would recognize many variations, alternatives, and modifications. As shown in FIG. 18, external interconnectors 1801 and 1802 are used to connect packaged solar cells in parallel. Packaged solar cells can be connected in series before connecting in parallel by external interconnectors.

According to an embodiment, the present invention provides a method for manufacturing a solar cell. The method includes providing a crystalline silicon substrate, the substrate being defined by a first thickness, the substrate including a first surface and a second surface, the first surface on an opposite side of the second surface. The method also includes forming a separation region within the first thickness, the separation region including hydrogen species, the separating region being substantially parallel to the first surface, the separation region defining a first portion and a second portion within the thickness, the first portion being within a second thickness from the first surface. Additionally, the method includes providing a mould structure on the first surface, the mould structure defining a support region. Furthermore, the method includes forming a layer of ceramic material within the support region. Also, the method includes removing the mould structure. Additionally, the method includes removing the second portion. Moreover, the method includes forming electrical devices on the first portion. For example, the method is illustrated in FIGS. 1-8.

According to another embodiment, the present invention provides a photovoltaic device. The device includes a supporting layer, the supporting layer consisting essentially of ceramic material, the supporting layer being characterized by a first thickness, the ceramic material being characterized by a gas permeability level, the supporting layer including a first surface and a second surface. The device also includes a photovoltaic layer including a first side and a second side, the photovoltaic layer being characterized by a thickness of less than ten microns, the photovoltaic layer overlying the first surface of the supporting layer, the first side being coupled to the supporting layer, the photovoltaic layer consisting essentially of silicon material. Additionally, the device includes a plurality of electrical contacts coupled to the photovoltaic layer. For example, the example is illustrated in FIG. 8.

According to yet another embodiment, the present invention provides a photovoltaic device. The device includes a supporting layer, the supporting layer consisting essentially of ceramic material, the supporting layer being characterized by a first thickness, the ceramic material being characterized by a gas permeability level, the supporting layer including a first surface and a second surface, the first surface being reflective, the ceramic supporting material being solidified from a fluidic ceramic material. The device can also include a bonding layer, the bonding layer including adhesive material. Furthermore, the device includes a photovoltaic layer including a first side and a second side, the photovoltaic layer including doped regions, the doped regions including a first type and a second type of impurities, layer being characterized by a thickness of less than ten microns, the photovoltaic layer overlying the first surface of the supporting layer, the first side being coupled to the supporting layer through the bonding layer, the photovoltaic layer consisting essentially of silicon material, the photovoltaic layer including doped regions. Also, the device includes a plurality of electrical contacts coupled to the photovoltaic layer. The example is illustrated in FIG. 8.

According to further embodiment, the present invention provides a packaged solar cells' structure for solar tile application. The packaged solar cell includes a photovoltaic device, the photovoltaic device including first side and second side and consisting of supporting layer and photovoltaic layer. The supporting layer is consisting essentially of ceramic material, the supporting layer being characterized by a first thickness, the ceramic material being characterized by a gas permeability level, the supporting layer including a first surface and a second surface. The photovoltaic layer includes a first side and a second side, the photovoltaic layer being characterized by a thickness of less than ten microns, the photovoltaic layer overlying the first surface of the supporting layer, the first side being coupled to the supporting layer, the photovoltaic layer consisting essentially of silicon material. The packaged solar cell also includes protective layer covering the first side and second side of photovoltaic device. The packaged solar cell further includes positive and negative electrical connectors, which can be done by conductive glue or soldering, connected to the solar cell metallization and provide electrical connection to other packaged solar cells in series. The example is illustrated in FIGS. 16 and 17. The present invention can also provide electrical connection of packaged solar cells in parallel. The example is illustrated in FIG. 18.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a hydrogen co-implant to form a thin layer of photovoltaic material. Since the layers are very thin, multiple layers of photovoltaic regions can be formed from a single conventional single crystal silicon or other like material wafer. In a preferred embodiment, the present thin layer removed by hydrogen implant and thermal treatment can be provided on a fluidic ceramic substrate material, which will serve as a support member. Furthermore, the present invention provides a packaged solar cells' structure for solar tile application. Depending upon the embodiment, one or more of these benefits may be achieved. These and other benefits will be described in more detail throughout the present specification and more particularly below.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for manufacturing a solar cell, the method comprising:
providing a crystalline silicon substrate, the substrate being defined by a first thickness, the substrate including a first surface and a second surface, the first surface on an opposite side of the second surface;
forming a separation region within the first thickness of the silicon substrate, the separation region including hydrogen species, the separating region being substantially parallel to the first surface, the separation region defining a first portion and a second portion within the thickness of the silicon substrate, the first portion being within a second thickness from the first surface;
providing a mould structure on the first surface, the mould structure defining a support region;
forming a layer of ceramic material within the support region;
removing the mould structure;
removing the second portion of the silicon substrate along the separation region; and
forming electrical devices on the first portion of the silicon substrate.

2. The method of claim 1 wherein the electrical devices include photovoltaic devices.

3. The method of claim 1 further comprising forming at least one layer selected from a diffusion barrier, an adhesive layer, a mirror layer or strengthening layer between the first portion and the ceramic material.

4. The method of claim 1 wherein the layer of ceramic material is gas permeable.

5. The method of claim 1 further comprising performing hydrogen implantation to introduce the hydrogen species into the silicon substrate.

6. The method of claim 1 wherein removing the second part of the silicon substrate along the separation region comprises a thermal exfoliation process.

7. The method of claim 1 wherein the ceramic material is a fluidic ceramic material.

8. The method of claim 6 further comprising solidifying the fluidic ceramic material.

9. The method of claim 1 further comprising:
defining a first region and a second region in the first portion of the silicon substrate, the first region and the second region being separated at least by a part of the first portion;
doping the first region with a first type of impurities;
doping the second region with a second type of impurities.

10. The method of claim 9 wherein the first type of impurities are n-type impurities and the second type of impurities are p-type impurities to form n-doped regions and p-doped regions of photovoltaic devices.

11. The method of claim 2 further comprising forming electrical contacts on the photovoltaic devices.

12. The method of claim 10 further comprising forming electrical connectors respectively to the n-doped regions and the p-doped regions of the photovoltaic devices.

13. The method of claim 1 wherein the first portion of the silicon substrate has a thickness of approximately two to ten microns.

14. The method of claim 2 further comprising:
forming a protective layer over the photovoltaic devices, the protective layer including weather resistant material;
forming one or more electrical connectors electrically communicating with the photovoltaic devices for electrical connection to other photovoltaic devices; and
forming a plurality of external interconnectors for electrical connection of the solar cell to other solar cells.

15. The method of claim 9 wherein the external interconnectors are male and female interconnectors.

16. A solar cell formed by the process of claim 1.

17. A solar cell formed by the process of claim 2.

18. A solar cell formed by the process of claim 10.

19. A solar cell formed by the process of claim 14.

20. A solar cell formed by the process of claim 15.
